(19) United States
(12) Patent Application Publication
(10) Pub. No.: US 2002/0135071 A1
(43) Pub. Date: Sep. 26, 2002

(54) Integrated circuit device contact plugs having a liner layer that exerts compressive stress thereon and methods of manufacturing same

(76) Inventors: Sang-Bom Kang, Seoul (KR); Seong-Geon Park, Kyungki-do (KR); Chang-Won Lee, Kyungki-do (KR); Gil-Heyun Choi, Kyungki-do (KR)

Correspondence Address: MYERS BIGEL SIBLEY & SAJOVEC, PO BOX 37428, RALEIGH, NC, 27627, US

(21) Appl. No.: 10/050,195

(22) Filed: Jan. 16, 2002

(30) Foreign Application Priority Data
Jan. 17, 2001 (KR) 2001-2639

(51) Int. Cl. H01L 29/40; H01L 23/52; H01L 23/48

(52) U.S. Cl. 257/767

(57) ABSTRACT

An integrated circuit device includes a substrate and an insulating layer that is disposed on the substrate and has a gap or hole formed therein. A liner layer that exhibits compressive stress characteristics is disposed on the sidewalls of the insulating layer, which define the gap, and also on the substrate in the gap. A contact plug that exhibits tensile stress characteristics is disposed on the liner layer. The compressive stress of the liner layer may reduce the tensile stress of the contact plug. Therefore, despite the tensile stress exhibited by the contact plug, the combination of the liner layer with the contact plug may inhibit the formation of cracks in the contact plug and/or in an interlayer dielectric film around the contact plug.

### RELATED APPLICATION

This application claims the benefit of Korean Patent Application No. 2001-2639, filed Jan. 17, 2001, the disclosure of which is hereby incorporated herein by reference.

1. Field of the Invention

The present invention relates generally to integrated circuit devices and manufacturing methods therefor and, more particularly, to integrated circuit device contact plugs and manufacturing methods therefor.

2. Background of the Invention

As the integration density of integrated circuit devices increases, the size of a contact plug for forming multi-layer wiring and the line width of metal wiring layers may decrease. Therefore, it may be desirable to form contact plugs using relatively low resistance metals to obtain high yield, high operating speed, and high reliability integrated circuit devices.

Contact plugs may be formed using tungsten (W) as a relatively low resistance metal. Typically, a Ti/TiN film is formed as an ohmic layer and a barrier film in the process of forming a W plug. As the critical dimension (CD) of a contact plug is reduced, however, it may be desirable to improve the relatively complicated series of processes for forming the contact plug by forming three layers of Ti, TiN, and W, respectively, and then etching the three layers. Also, when a contact plug comprises W and a metal wiring layer also comprises W, some or all of the W contact plug may be removed by over etching when the W contact plug is exposed during a dry etching process for forming the metal wiring layer. In general, the narrower the line width of the metal wiring layer, the more susceptible the contact plug is to over etching. Therefore, it may be desirable to use different materials for forming a contact plug and a metal wiring layer.

Polysilicon may be used to form a contact plug for use as a buried contact for electrically connecting a capacitor lower electrode of a memory device to an active region of a semiconductor substrate. When the capacitor comprises a metal-insulator-metal (MIM) structure, the polysilicon contact plug contacts the metal lower electrode of the MIM structure. When a thermal process used to form a dielectric film is performed, the polysilicon comprising the contact plug may be oxidized. Accordingly, SiO₂, which is a nonconductor, may be formed on the contact plug. Therefore, it may be desirable to use an oxidation-tolerant material when forming a contact plug for use as a buried contact.

A contact plug that comprises a TiN film may be formed by a chemical vapor deposition (CVD) process using TiCl₄ and NH₃ precursors (hereinafter a CVD-TiN film). Because the CVD-TiN film has generally good step coverage, it may be used to form contact plugs having a large aspect ratio. Because the CVD-TiN film has relatively high tensile stress, however, when the CVD-TiN film is deposited to a thickness more than 50 nm, cracks may be generated in the CVD-TiN film and also in an interlayer dielectric film around the CVD-TiN film. To completely fill the contact plug space with the CVD-TiN film, TiN is typically deposited to a thickness of more than half of the contact plug CD to be formed. For example, to form a TiN contact plug having a CD of 200 nm, TiN may be deposited to a thickness of more than 100 nm. Because cracks may be generated when the thickness of the CVD-TiN film is more than 50 nm, it may be difficult to use CVD-TiN film to form contact plugs having a CD greater than 100 nm.

### SUMMARY OF THE INVENTION

According to embodiments of the present invention, an integrated circuit device comprises a substrate and an insulating layer that is disposed on the substrate and has a gap or hole formed therein. A liner layer that exhibits compressive stress characteristics is disposed on the sidewalls of the insulating layer, which define the gap, and also on the substrate in the gap. A contact plug that exhibits tensile stress characteristics is disposed on the liner layer. Advantageously, the compressive stress of the liner layer may reduce the tensile stress of the contact plug. Therefore, despite the tensile stress exhibited by the contact plug, the combination of the liner layer with the contact plug may inhibit the formation of cracks in the contact plug and/or in an interlayer dielectric film around the contact plug regardless of the thickness of the contact plug.

In other embodiments, the liner layer and the contact plug comprise titanium nitride (TiN).

In still other embodiments, the liner layer is formed using one of the following methods: ionized physical vapor deposition (IPVD), metal organic chemical vapor deposition (MOCVD), metal organic atomic layer deposition (MOALD), sputtering, and collimator sputtering.

In further embodiments, the contact plug is formed using one of the following methods: chemical vapor deposition (CVD), atomic layer deposition (ALD), MOCVD, and MOALD.

In further embodiments, an ohmic layer is disposed between the liner layer and the sidewalls of the insulating layer, and between the liner layer and the substrate.

In still further embodiments, a wiring layer is disposed on an upper surface of the contact plug opposite the substrate.

In still further embodiments, a capacitor is disposed on an upper surface of the contact plug opposite the substrate.

### BRIEF DESCRIPTION OF THE DRAWINGS

Other features of the present invention will be more readily understood from the following detailed description of specific embodiments thereof when read in conjunction with the accompanying drawings, in which:

FIGS. 1, 2, 3A-3E, and 4A-4D are cross sectional views that illustrate integrated circuit device contact plugs having a liner layer that exerts compressive stress thereon and methods of manufacturing same in accordance with embodiments of the present invention.

### DETAILED DESCRIPTION OF PREFERRED EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the figures, the dimensions of layers and regions are exaggerated for clarity. It will also be understood that when an element, such as a layer, region, or substrate, is referred to as being “on” another element, it can be directly on the other element or intervening elements may be present. In contrast, when an element, such as a layer, region, or substrate, is referred to as being “directly on” another element, there are no intervening elements present.

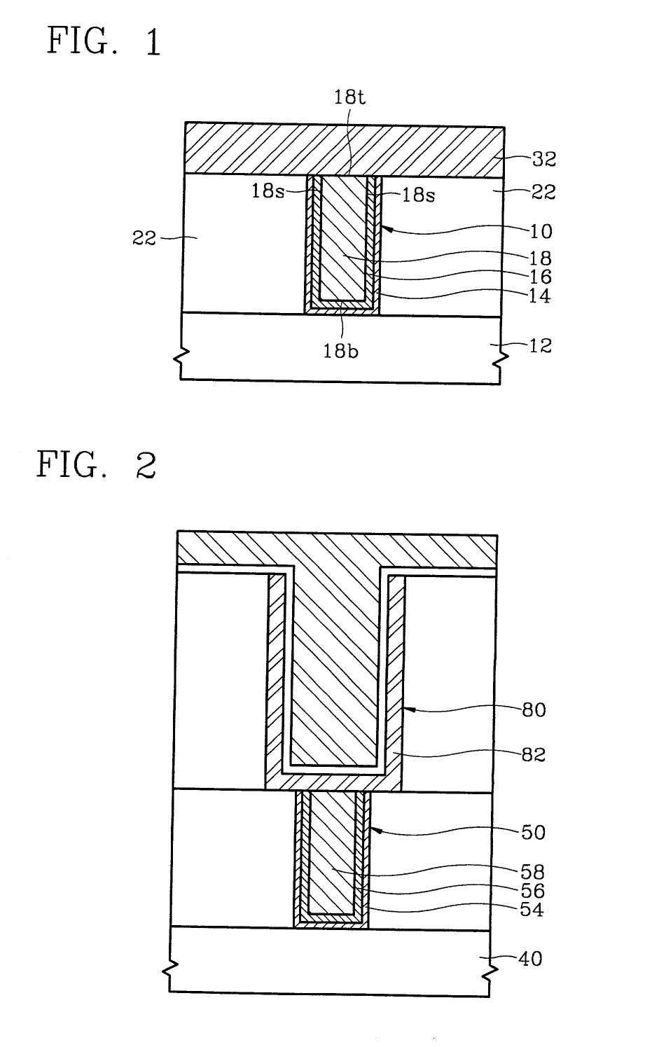

Referring now to FIG. 1, a contact plug 10, according to embodiments of the present invention, is formed so as to pass through an insulating film 22 interposed between a conductive region (not shown) on a semiconductor substrate 12 and a metal wiring layer 32 on the insulating film 22 to electrically connect the conductive region to the metal wiring layer 32. The metal wiring layer 32 may comprise, for example, a wiring layer and/or an Al wiring layer, and may be part of a multi-layer wiring structure.

The contact plug 10 comprises a TiN plug 18, which exhibits tensile stress characteristics and a TiN liner 16, which exhibits compressive stress characteristics. A Ti ohmic layer 14 is formed between the TiN liner 16 and the insulating film 22, and between the TiN liner 16 and the conductive region of the semiconductor substrate 12.

The upper surface 18t of the TiN plug 18 contacts the upper wiring layer 32, and the sidewall 18s and the bottom surface 18b of the TiN plug 18 contact the TiN liner 16. In other words, the TiN liner 16 surrounds the sidewall 18s and the bottom surface 18b of the TiN plug 18. In some embodiments, the TiN plug 18 maybe formed so that the width of the upper surface 18t is approximately equal to the width of the bottom surface 18b. In other embodiments, the TiN plug 18 may be formed so that the width of the upper surface 18t is greater than the width of the bottom surface 8b. The Ti ohmic layer 14 contacts the TiN liner 16 on the opposite side of the TiN plug 18.

The TiN plug 18 may comprise a TiN film formed using chemical vapor deposition (CVD), atomic layer deposition (ALD), metal organic CVD (MOCVD), or metal organic ALD (OALD). The TiN liner 16 may comprise a TiN film formed using ionized physical vapor deposition (IPVD), MOCVD, MOALD, sputtering, or collimator sputtering.

The TiN liner 16 may inhibit the generation of cracks in the contact plug 10 and the insulating film 22 around the contact plug 10 by buffering the tensile stress of the TiN plug 18. The TiN liner 16 may have an amorphous crystal structure. To facilitate formation of an amorphous crystal structure, the TiN liner 16 may be formed using IPVD. A TiN film obtained using MOCVD or MOALD may exhibit tensile stress characteristics or compressive stress characteristics based on process variables used in the deposition process, such as the process gas mass flow and the deposition temperature. Therefore, a TiN film may be formed that exhibits tensile stress characteristics or compressive stress characteristics by appropriately controlling deposition process variables.

Referring now to FIG. 2, a contact plug 50, according to other embodiments of the present invention, is used as a buried contact to electrically connect a lower electrode 82, which comprises part of an integrated circuit memory device capacitor 80, to an active region (not shown) on an integrated circuit substrate 40. If the capacitor 80 comprises a metal-insulator-metal (MIM) structure, then the lower electrode 82 may comprise a single film formed of a metal, such as W, Pt, Ru, and/or Ir, a conductive metal nitride, such as TiN, TaN, and/or WN, and/or a conductive metal oxide, such as RuO_{2 and IrO}_{2 .}

A TiN plug 58, a TiN liner 56, and a Ti ohmic layer 54, which comprise the contact plug 50, may have the same structures as the TiN plug 18, the TiN liner 16, and the Ti ohmic layer 14, respectively, which have been described above with reference to FIG. 1.

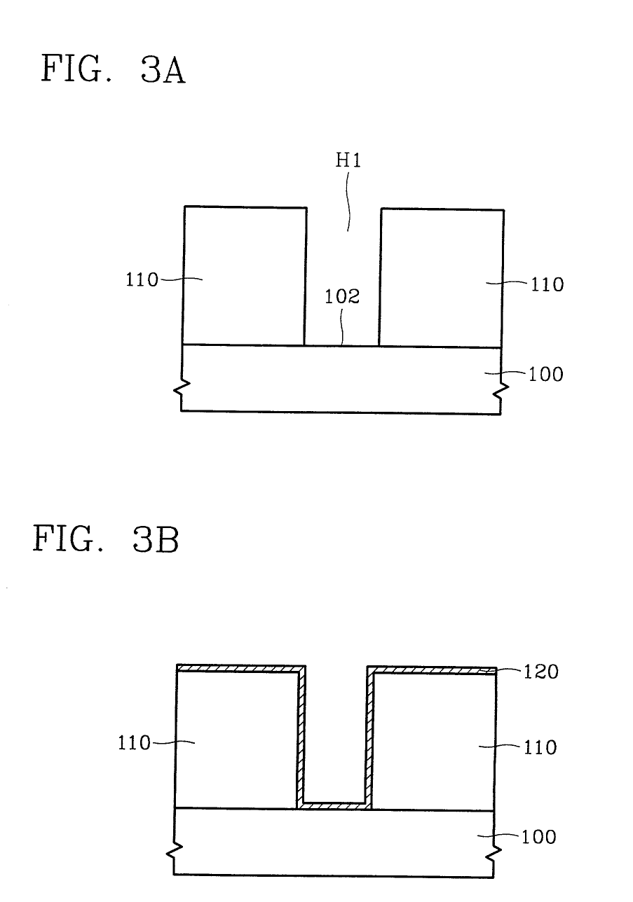

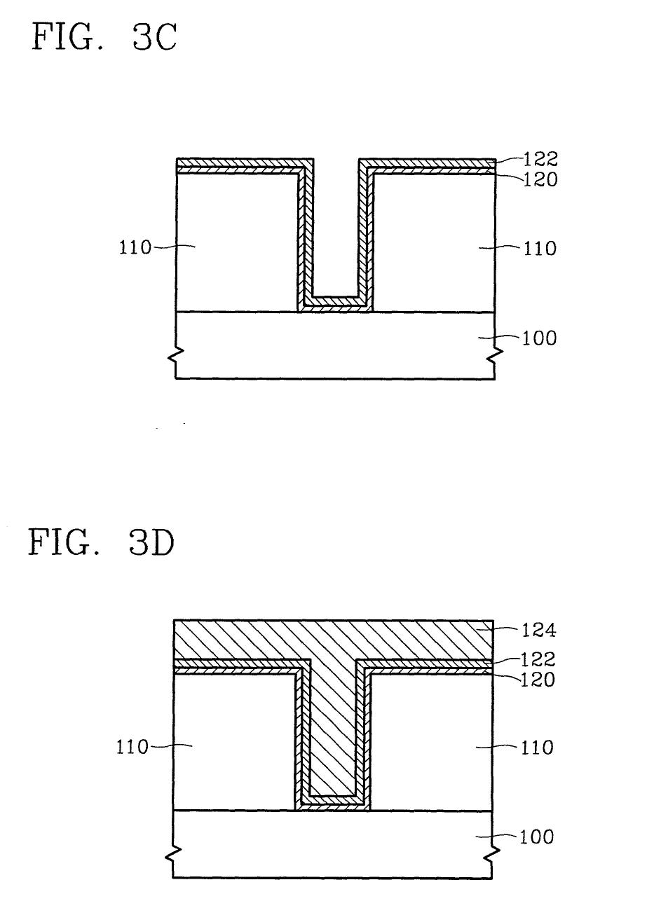

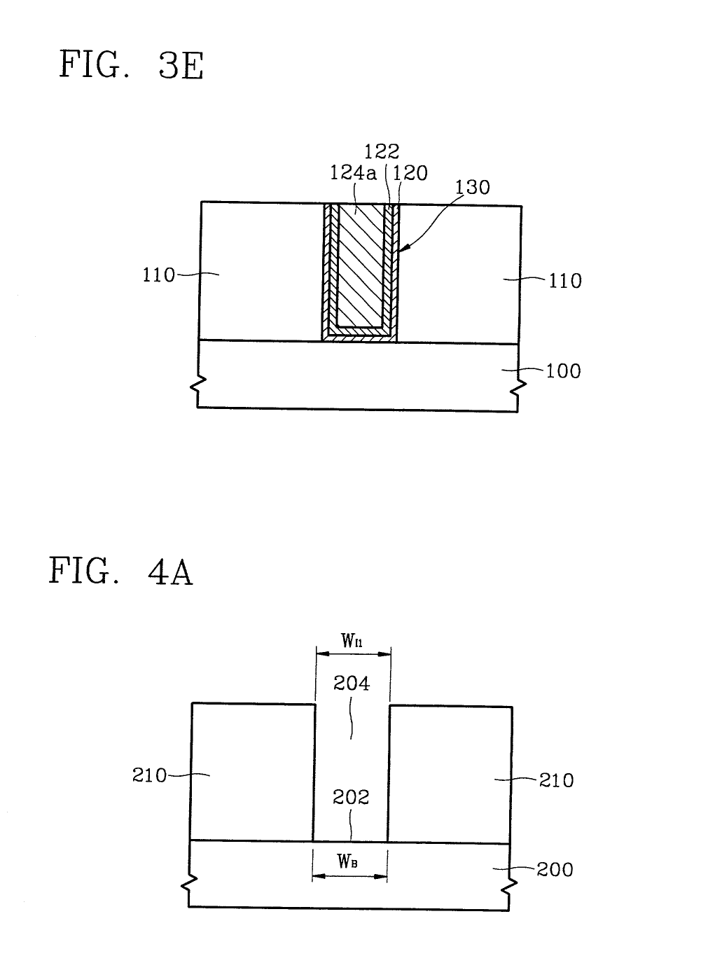

FIGS. 3A through 3E are cross-sectional views that illustrate methods of manufacturing integrated circuit device contact plugs and integrated circuit devices formed thereby in accordance with embodiments of the present invention.

Referring now to FIG. 3A, an insulating layer 110 is formed on a semiconductor substrate 100. The insulating layer 110 is etched to define a contact hole or gap H1 therein, which exposes a conductive region 102 in the semiconductor substrate 100.

Referring now to FIG. 3B, an ohmic layer 120 is formed on the entire surface of the structure of FIG. 3A to a thickness of about 70 Å- 100 Å so as to cover the inside wall of the contact hole H1. The ohmic layer 120 may comprise a Ti film formed using plasma enhanced CVD (PECVD), collimator sputtering, IPVD, or physical vapor deposition (PVD).

Referring now to FIG. 3C, a TiN liner 122, which exhibits compressive stress characteristics, is formed on the ohmic layer 120 to a thickness of about 200 Å-500 Å. The TiN liner 122 may be formed by depositing TiN using IPVD, MOCVD, MOALD, sputtering, or collimator sputtering. If the TiN liner 122 is formed by depositing TiN using IPVD, then the TiN liner 122 may have an amorphous crystal structure.

Referring now to FIG. 3D, a TiN film 124, which exhibits tensile stress characteristics, is formed on the structure of FIG. 3C so as to completely fill the contact hole H1. The TiN film 124 may be formed by depositing TiN using CVD, ALD, MOCVD, or MOALD. Advantageously, forming the TiN film 124 using the aforementioned methods may allow the TiN film 124 to exhibit relatively good step coverage in filling the contact hole H1.

In some embodiments, the TiN film 124 may be formed using CVD or ALD in. which TiCl₄ and NH₃ are used as precursors. In other embodiments, the TiN film 124 may be formed using MOCVD or MOALD in which a precursor, such as tetrakis di-methyl amido titanium (TDMAT) and tetrakis di-ethyl amido titanium (TDEAT) together with NH₃ or H₂, may be used.

In general, because TiN films formed using CVD or ALD exhibit relatively large tensile stress characteristics, cracks may be generated when the thickness of the TiN film is greater than 50 nm. A TiN film formed using MOCVD or MOALD may exhibit tensile stress characteristics by appropriately controlling deposition process variables, such as the process gas mass flow and the deposition temperature. Even though the TiN film 124 may exhibit tensile stress characteristics, this tension may be reduced due to the compressive stress exhibited by the TiN liner 122, which is formed before forming the TiN film 124 as described above with reference to FIG. 3C. If the TiN liner 122 is formed using IPVD, then the TiN liner 122 may have an amorphous crystal structure and the fine structure and the crystal direction of TiN deposited on the TiN liner 122 may be changed. The TiN liner 122 may, therefore, affect the fine structure and the crystal direction of the TiN film 124 formed thereon. As a result, the compressive stress exhibited by the TiN liner 122 may reduce the tensile stress exhibited by the TiN film 124. Thus, the combination of the TiN liner 122 with the TiN film 124 may inhibit the formation of cracks in the TiN film 124 and/or the insulating film 110.

TiN films formed using MOCVD or MOALD in which metallo-organics are used generally exhibit relatively small stress characteristics on the order of about 10⁹. The compressive and/or tensile stress characteristics of a TiN film may be adjusted based on the deposition process control variables. The TiN liner 122 and the TiN film 124 may be formed to have desired stress characteristics using MOCVD and/or MOALD after forming the ohmic layer 120 in the contact hole H1.

Referring now to FIG. 3E, the insulating layer pattern 110 is exposed by planarizing the structure of FIG. 3D by performing, for example, chemical mechanical polishing (CMP) or etching. A contact plug 130 may be formed, which comprises the ohmic layer 120, the TiN liner 122, and a TiN plug 124 a, inside the contact hole H1.

As described above with reference to FIGS. 3A through 3E, the TiN liner 122 may be formed using IPVD. When a TiN film is formed in a contact hole using IPVD, a void may be formed in the resulting contact plug after the contact hole is filled. Exemplary methods for inhibiting the formation of a void, in accordance with embodiments of the present invention, will now be described.

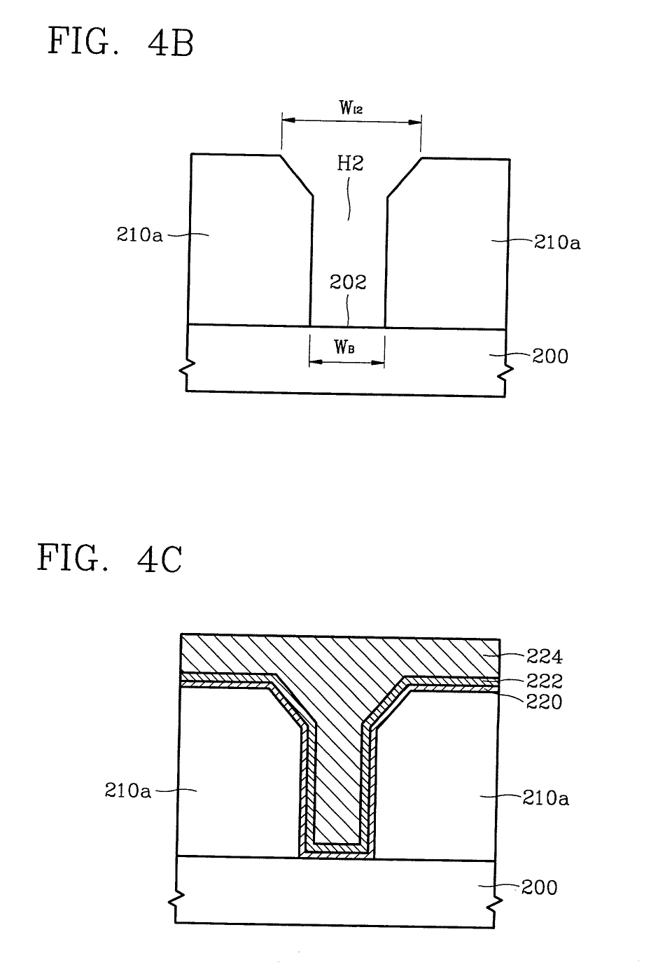

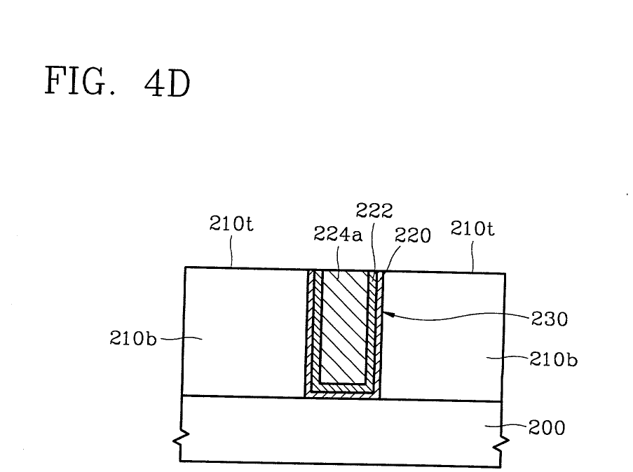

FIGS. 4A through 4D are cross-sectional views that illustrate methods of manufacturing integrated circuit device contact plugs and integrated circuit devices formed thereby in accordance with further embodiments of the present invention.

Referring now to FIG. 4A, an insulating film pattern 210 is formed on a semiconductor substrate 200. The insulating film pattern 210 is anisotropically etched to define a contact hole or gap therein, which exposes a conductive region 202 in the semiconductor substrate 200. The width Wₙ at the entrance of the hole is approximately equal to the width W_{B} at the bottom of the hole where the conductive region 202 is exposed.

Referring now to FIG. 4B, a second insulating film pattern 210a is formed by isotropically etching a portion around the entrance of the insulating film pattern 210 to define a contact hole H2 in which the width W₁₂ at the entrance of the contact hole H2 is greater than the previous width Wₙ of the hole entrance, and is also greater than the width W_{B} at the bottom of the contact hole. The isotopic etching may be performed using wet etching and a photoresist pattern as an etching mask.

Referring now to FIG. 4C, an ohmic layer 220, a TiN liner 222 that exhibits compressive stress characteristics, and a TiN film 224 that exhibits tensile stress characteristics are formed on the structure of FIG. 4B as described above with reference to FIGS. 3B through 3D. Because the entrance to the contact hole H2 has a relatively large width W_{I2}, there may be a reduced probability that the ohmic layer 220, the TiN liner 222, and the TiN film 224, which are formed in the contact hole H2 will contain a void. The compressive stress exhibited by the TiN liner 222 may reduce the tensile stress exhibited by the TiN film 224. Thus, the combination of the TiN liner 222 with the TiN film 224 may inhibit the formation of cracks in the TiN film 224 and/or the second insulating film pattern 210a.

Referring now to FIG. 4D, the upper surface 210t of a planarized second insulating film pattern 210b is exposed by planarizing the structure of FIG. 4C by performing, for example, chemical mechanical polishing (CMP) or etching. A contact plug 230 may be formed, which comprises the ohmic layer 220, the TiN liner 222, and a TiN plug 224a, inside the contact hole H2. Advantageously, according to embodiments of the present invention, the contact plug 230 may have a reduced susceptibility to cracking and the formation of voids therein.

Table 1 contains experimental results, which were obtained by estimating the stress of various kinds of TiN films and which can be used for forming contact plugs according to embodiments of the present invention. The results of Table 1 were obtained by forming TiN films on a plurality of silicon substrates to a thickness of 1000 Å and then measuring the stresses on these films.

TABLE 1

| Deposition method for forming TiN film | Stress (dyne/cm²) |
|---|---|
| Sputtering method | −1.61E10 (compressive stress) |
| Collimator sputtering method | −2.5E10 (compressive stress) |
| IPVD (SIP) | −3.3E10 (compressive stress) |
| IPVD (IMP) | −4.3E10 (compressive stress) |
| CVD | +1E10 through +3E10 |
| | (tensile stress) |
| ALD | +1E10 through +3E10 |
| | (tensile stress) |

In Table 1, IPVD (SIP) means the IPVD in a self-ionized plasma (SIP), and IPVD (IMP) means IPVD in an ionized metal plasma (IMP). The results of Table 1, show TiN films formed by sputtering, collimator sputtering, IPVD (SIP), and IPVD (IMP), exhibit compressive stress characteristics. TiN films formed by CVD and ALD, in which TiCl₄ is used as the precursor, exhibit relatively high tensile stress characteristics on the order of 10¹⁰ dynes/cm².

Based on the above results, if a TiN film is formed to a thickness of more than 50 nm by CVD or ALD, then cracks generated in the TiN film and/or an interlayer dielectric film surrounding the TiN film may be caused by the relatively high tensile stress characteristics of the TiN film. According to embodiments of the present invention, when forming a TiN contact plug, a TiN liner that exhibits compressive stress may be formed around a TiN plug to reduce the tensile stress in the TiN contact plug. Thus, through use of a TiN liner that exhibits compressive stress, it may be possible to reduce the susceptibility of a TiN film formed by CVD or ALD to cracks regardless of the thickness of the TiN film. A TiN liner formed using IPVD may exhibit compressive stress characteristics and may have an amorphous crystal structure. Moreover, the fine structure and the crystal direction of TiN deposited on the TiN liner may be changed. It has been confirmed through experiments and observations using a scanning electron microscope (SEM) that a TiN film that is affected by the crystal structure of an underlayer as discussed above may be less likely to crack.

Embodiments of the present invention have been described in the context of forming a contact plug by forming a TiN plug that exhibits tensile stress characteristics after forming a TiN liner that exhibits compressive stress characteristics. It will be understood, however, that the present invention is not limited to these exemplary embodiments. For example, in other embodiments, a contact plug may be formed by using a multi-step process of repeatedly forming a TiN film that exhibits compressive stress characteristics and forming a TiN film that exhibits tensile stress characteristics so as to overlap the TiN film having the compressive stress characteristics and the TiN film having the tensile stress characteristics.

According to embodiments of the present invention, a contact plug may be formed by forming an ohmic layer, forming a TiN liner that exhibits compressive stress characteristics on the ohmic layer, and then forming a TiN plug that exhibits tensile stress characteristics on the TiN liner. Advantageously, the compressive stress of the TiN liner may reduce the tensile stress of the TiN plug. In particular, if the TiN liner is formed using IPVD, then the TiN liner may have an amorphous crystal structure. Moreover, the fine structure and the crystal direction of TiN deposited on the TiN liner may be changed. Therefore, despite the relatively large tensile stress exhibited by the TiN film, the combination of the TiN liner with the TiN film may inhibit the formation of cracks in the TiN film and/or in an interlayer dielectric film around the TiN film regardless of the thickness of the TiN film.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

We claim:

1. An integrated circuit device, comprising:
a substrate;
an insulating layer disposed on the substrate having a gap formed therein;
a liner layer that exhibits compressive stress characteristics disposed on sidewalls of the insulating layer, which define the gap, and on the substrate in the gap; and
a contact plug that exhibits tensile stress characteristics disposed on the liner layer.

2. The integrated circuit device of claim 1, wherein the liner layer and the contact plug comprise titanium nitride (TiN).

3. The integrated circuit device of claim 1, wherein the liner layer has an amorphous crystal structure.

4. The integrated circuit device of claim 1, further comprising:
an ohmic layer disposed between the liner layer and the sidewalls of the insulating layer, and between the liner layer and the substrate.

5. The integrated circuit device of claim 4, wherein the ohmic layer comprise titanium (Ti).

6. The integrated circuit device of claim 4, wherein the ohmic layer has a thickness of about 70 Å-100 Å.

7. The integrated circuit device of claim 1, wherein the liner layer has a thickness of about 200 Å-500 Å.

8. The integrated circuit device of claim 1, further comprising:
a wiring layer disposed on an upper surface of the contact plug opposite the substrate.

9. The integrated circuit device of claim 1, wherein the wiring layer comprises a metal material.

10. The integrated circuit device of claim 1, wherein the wiring layer comprises at least one of tungsten (W) and aluminum (Al).

11. The integrated circuit device of claim 1, further comprising:
a capacitor disposed on an upper surface of the contact plug opposite the substrate.

12. The integrated circuit device of claim 1, wherein the capacitor comprises a lower electrode that contacts the upper surface of the contact plug.

13. The integrated circuit device of claim 12, wherein the lower electrode comprises at least one of the following materials: W, Pt, Ru, Jr, TiN, TaN, WN, RuO₂, and IrO₂.

14. The integrated circuit device of claim 1, wherein the gap is wider at a surface of the insulating layer opposite the substrate than it is at another location.

15. A method of forming an integrated circuit device, comprising:
forming an insulating layer on a substrate;
etching the insulating layer so as to form a gap therein, which exposes the substrate;
forming a TiN liner layer on sidewalls of the insulating layer, which define the gap, and on the substrate in the gap using a method selected from the group of methods consisting of: ionized physical vapor deposition (IPVD), metal organic chemical vapor deposition (MOCVD), metal organic atomic layer deposition (MOALD), sputtering, and collimator sputtering; and
forming a TiN film on the liner layer using a method selected from the group of methods consisting of: chemical vapor deposition (CVD), atomic layer deposition (ALD), MOCVD, and MOALD.

16. The method of claim 15, further comprising performing the following before forming the TiN liner layer:
forming an ohmic layer on the sidewalls of the insulating layer and on the substrate in the gap; and
wherein forming the TiN liner layer comprises forming the TiN liner layer on the ohmic layer.

17. The method of claim 16, wherein the ohmic layer comprises Ti, and wherein forming the ohmic layer comprises:
forming the ohmic layer using a method selected from the group of methods consisting of plasma enhanced chemical vapor deposition (PECVD), collimator sputtering, IPVD, and PVD.

18. The method of claim 15, wherein forming the TiN liner layer comprises forming the TiN liner layer using IPVD, and wherein the TiN liner layer has an amorphous crystal structure.

19. The method of claim 15, wherein forming the TiN film comprises forming the TiN film using a method selected from the group of methods consisting of CVD and ALD and using TiCl₄ and NH₃ as precursors.

20. The method of claim 15, wherein forming the TiN film comprises forming the TiN film using a method selected from the group of methods consisting of MOCVD and MOALD and using tetrakis di-methyl amido titanium (TDMAT) and tetrakis di-ethyl amido titanium (TDEAT) as precursors.

21. The method of claim 15, further comprising:
exposing the insulating layer by performing at least one of the following:
chemical mechanical polishing the TiN film; and
etching the TiN film.

22. The method of claim 15, wherein etching the insulating layer comprises:
etching the insulating layer such that the gap is wider at a surface of the insulating layer opposite the substrate than it is at another location.

23. The method of claim 15, wherein the ohmic layer has a thickness of about 70 Å-100 Å.

24. The method of claim 15, wherein the TiN liner layer has a thickness of 0about 200 Å-500 Å.

25. A contact plug of a semiconductor device formed through an insulating film interposed between a lower conductive layer and an upper conductive layer to electrically connect the lower conductive layer to the upper conductive layer, comprising:
a TiN plug having an upper surface contacting the upper conductive layer and having tensile stress;
a TiN liner contacting the TiN plug so as to surround the TiN plug along the side wall and the bottom of the TiN plug and having compressive stress; and
an ohmic layer contacting the TiN liner on the opposite side of the TiN plug and located between the TiN liner and the insulating film and between the TiN liner and the lower conductive layer.

26. The contact plug of claim 25, wherein the TiN plug comprises a TiN film formed by chemical vapor deposition (CVD), atomic layer deposition (ALD), metal organic CVD (MOCVD), or metal organic ALD (MOALD).

27. The contact plug of claim 25, wherein the TiN liner comprises a TiN film formed by ionized physical vapor deposition (IPVD), metal organic CVD (MOCVD), metal organic ALD (MOALD), sputtering, or collimator sputtering.

28. The contact plug of claim 25, wherein the TiN liner has an amorphous structure.

29. The contact plug of claim 28, wherein the TiN liner comprises a TiN film formed by ionized physical vapor deposition (IPVD).

30. The contact plug of claim 25, wherein the TiN plug has a bottom surface, which contacts the TiN liner, and the upper surface of the TiN plug has a width greater than the width of the bottom surface.

31. The contact plug of claim 25, wherein the upper conductive layer comprises at least one film selected from the group of films consisting of W, Al, Pt, Ru, Ir, TiN, TaN, WN, RuO₂, and IrO₂.

32. The contact plug of claim 25, wherein the upper conductive layer comprises the lower electrode of a capacitor.

33. A method for forming a contact plug of a semiconductor device, comprising the steps of:
forming an insulating film pattern for defining a contact hole exposing a conductive region on a semiconductor substrate by etching an insulating film formed on the semiconductor substrate;
forming an ohmic layer on a resulting structure after forming the insulating film pattern so as to cover an inside wall of the contact hole;
forming a TiN liner having compressive stress on the ohmic layer; and
forming a TiN plug having tensile stress on the TiN liner so that the contact hole is filled.

34. The method of claim 33, wherein the ohmic layer comprises a Ti film formed by plasma enhanced chemical vapor deposition (PECVD), collimator sputtering, ionized physical vapor deposition (IPVD), or physical vapor deposition (PVD).

35. The method of claim 33, wherein the step of forming the TiN liner is performed by ionized physical vapor deposition (IPVD), metal organic chemical vapor deposition (MOCVD), metal organic atomic layer deposition (MOALD), sputtering, or collimator sputtering.

36. The method of claim 33, wherein the TiN liner has an amorphous crystal structure.

37. The method of claim 36, wherein the step of forming the TiN liner is performed by ionized physical vapor deposition (IPVD).

38. The method of claim 33, wherein the step of forming the TiN plug comprises the steps of:
forming a TiN film having tensile stress on the TiN liner so as to fill the contact hole; and
planarizing a resultant structure on which the TiN film is formed so that the insulating film pattern is exposed.

39. The method of claim 38, wherein the step of forming the TiN film is performed by chemical vapor deposition (CVD), atomic layer deposition (ALD), metal organic CVD (MOCVD), or metal organic ALD (MOALD).

40. The method of claim 33, wherein the width of an entrance of the contact hole is substantially equal to the width of a bottom of the contact hole, through which the conductive region is exposed.

41. The method of claim 33, wherein the width of an entrance of the contact hole is greater than a width of a bottom of the contact hole, through which the conductive region is exposed.

42. The method of claim 41, wherein the step of forming the insulating film pattern comprises the steps of:
forming a first insulating film pattern defining a first hole having an entrance of a first width by anisotropically etching the insulating film so as to expose the conductive region; and
forming a second insulating film pattern defining the contact hole having an entrance of a second width greater than the first width by isotropically etching a portion around the entrance of the first hole in the first insulating film pattern.

43. The method of claim 42, wherein the step of isotropically etching the insulating film pattern is performed by dry etching or wet etching.

44. The method of claim 33, wherein the TiN liner and the TiN plug are formed by metal organic chemical vapor deposition (MOCVD) or metal organic atomic layer deposition (MOALD).
